(19) United States
(12) Patent Application Publication
(10) Pub. No.: US 2024/0071891 A1
(43) Pub. Date: Feb. 29, 2024

(54) SEMICONDUCTOR DEVICE ASSEMBLIES HAVING FACE-TO-FACE SUBASSEMBLIES, AND METHODS FOR MAKING THE SAME

(71) Applicant: Micron Technology, Inc., Boise, ID (US)

(72) Inventor: Thiagarajan Raman, Boise, ID (US)

(21) Appl. No.: 17/899,577

(22) Filed: Aug. 30, 2022

(51) Int. Cl. H01L 23/498; H01L 21/48; H01L 21/56; H01L 23/00; H01L 25/065

(52) U.S. Cl. CPC H01L 23/49838; H01L 21/4853; H01L 21/565; H01L 23/49811; H01L 23/49833; H01L 23/49894; H01L 24/16; H01L 24/32; H01L 24/48; H01L 25/0657; H01L 2224/16225; H01L 2224/32145; H01L 2224/48225; H01L 2225/06524; H01L 2225/06541; H01L 2225/06565; H01L 2924/1436; H01L 2924/1438; H01L 2924/182

(57) ABSTRACT

A semiconductor device assembly having face-to-face subassemblies is provided. The assembly includes a first and second semiconductor device subassembly. Both subassemblies include a substrate, a stack of semiconductor dies, and an interconnect structure. The interconnect structures include a conductive pillar surrounded by dielectric material. Both substrates form opposing outer sides of the assembly, while the interconnect structures are disposed on the inside surface of their respective substrates and are directly coupled to one another. The die stacks are shorter than their respective interconnect structures, and therefore can also be disposed on the inside surface of their respective substrates. An encapsulant material—comprising a different material than the dielectric material—at least partially encapsulates the stacks and the interconnect structures.

### TECHNICAL FIELD

The present disclosure generally relates to semiconductor device assemblies, and more particularly relates to semiconductor device assemblies having face-to-face subassemblies, and methods for making the same.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

FIG. 1 is a simplified schematic cross-sectional view of a semiconductor device assembly in accordance with embodiments of the present technology.

FIGS. 2-3 are simplified schematic cross-sectional views of semiconductor device subassemblies in accordance with embodiments of the present technology.

FIG. 4 is a simplified schematic cross-sectional view of a composite interconnect structure of a semiconductor device assembly in accordance with embodiments of the present technology.

FIGS. 5-6 are simplified schematic oblique views of semiconductor device subassemblies in accordance with embodiments of the present technology.

FIG. 7 is a schematic view showing a system that includes a stacked semiconductor device assembly in a mirrored architecture configured in accordance with an embodiment of the present technology.

FIG. 8 is a flow chart illustrating a method of making a stacked semiconductor device assembly in a mirrored architecture in accordance with an embodiment of the present technology.

### DETAILED DESCRIPTION

The electronics industry relies upon continuous innovation in the field of semiconductor packaging to meet the global need for higher-functioning technology. This demand calls for increasingly complicated assemblies of semiconductor devices, which may diverge in terms of plan area, thickness, connection methodology, etc. One approach to accommodate the packaging of such varied devices into a single assembly is to layer semiconductor devices into a stack. Stacks, however, have many disadvantages.

One disadvantage is the need to keep the stack thermally and mechanically stable on the substrate. At the same time, the resulting package must be as thin as possible, with die interconnections that are electrically good and reliable. Another disadvantage in die stacking is the difficulty in picking known good die (KGD) from a wafer. Including a single defective die can ‘kill’ the entire stack and result in yield losses and higher costs. Die stacking, therefore, becomes less attractive as the number of die in the stack increases and as the die involved become more expensive or complex.

To address these drawbacks and others, various embodiments of the present disclosure provide semiconductor device assemblies having face-to-face sub-assemblies.

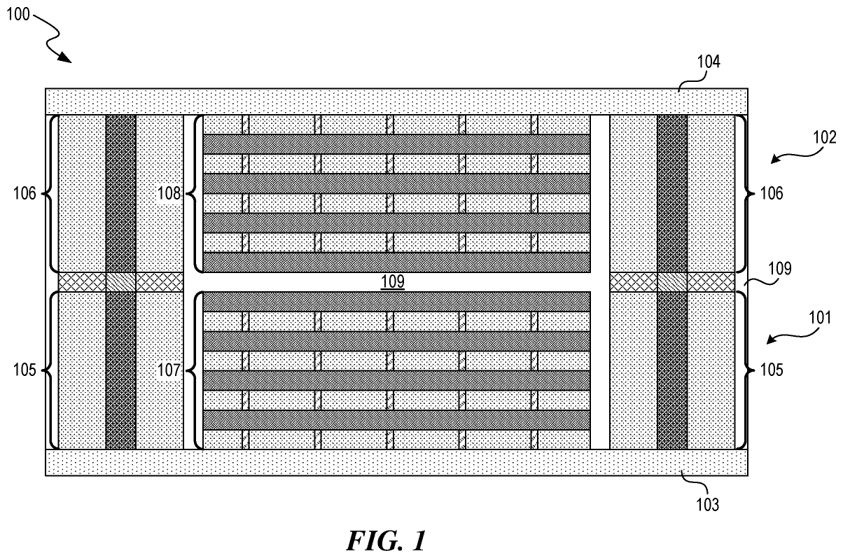

FIG. 1 is a simplified schematic cross-sectional view of a stacked semiconductor device assembly in a mirrored architecture 100 in accordance with embodiments of the present technology. The assembly 100 includes a first subassembly 101 and a second subassembly 102, each with their own die stack 107 and 108. These stacks 107 and 108 can be separated and enclosed by a molding material (e.g., encapsulant, adhesive, etc.) 109, and can be disposed on the inside surface of their own substrates 103 and 104 (e.g., a printed circuit board (PCB), an interface die, etc.), which can form external opposing sides of the assembly 100. The die stacks 107 and 108 can be electrically coupled to their corresponding substrates 103 and 104 (e.g., through solder bumps, wire bonds, traces, vias, pads, etc.). There may be a gap between the first and second die stack 107 and 108, which can be at least partially filled with an adhesive material.

Arranging the total number of dies provided into two separate stacks reduces the impact of including a single bad die in one of the stacks (i.e., reducing the number of wasted “good” dies), and still maintains almost an equivalent footprint as die grouped in the single stack. This modularization is achieved through the use of interconnect structures 105 and 106, which can be connected to their substrates 103 and 104, respectively. In this regard, the interconnect structures 105 and 106 may be soldered to pads located on an inside surface of their substrates 103 and 104, respectively. In addition to providing the assembly 100 with conductive paths between the subassemblies 101 and 102, the interconnect structures 105 and 106 can also provide the assembly 100 with its structural stability.

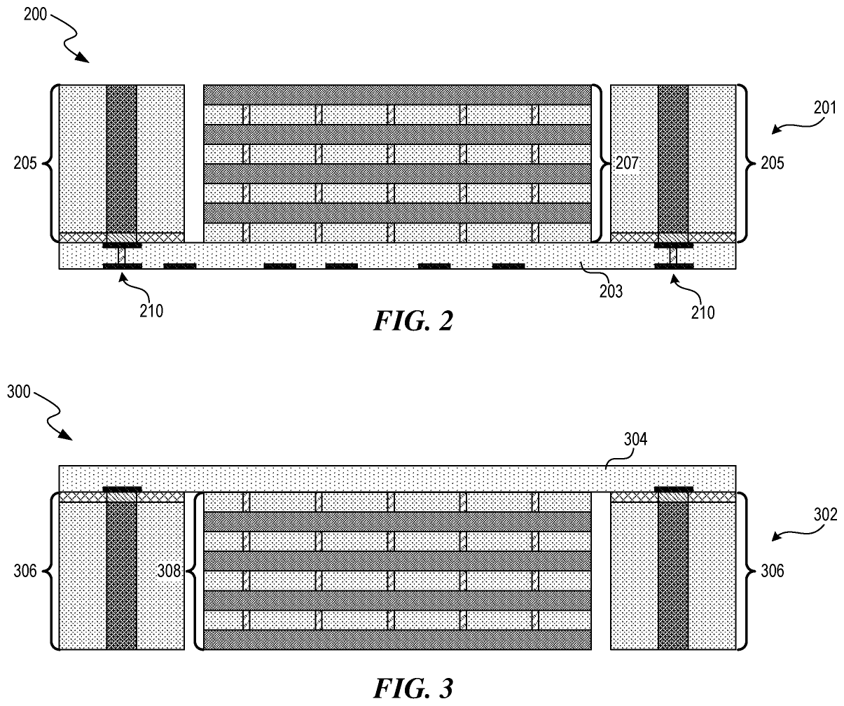

While these subassemblies 101 and 102 appear similar, in some embodiments there can exist several differences between them. Some such differences are highlighted in FIG. 2 and FIG. 3, which represent embodiments of the first and second subassembly 201 and 302, respectively. The second subassembly 302 can have a substrate 304 that is without any conductive structures or contacts on its outer surface, while the first subassembly 201 can have a first substrate 203 that does have external connections 210. These external connections 210 can bond to a first die stack 207 through a direct connection (e.g., solder bumps, wire bonds, traces, vias, pads, etc.), while a portion of the external connections 210 can reach the second substrate 304, and then on to a second die stack 308 that is directly connected to the substrate 304. Achieving this connection are a first and a second interconnect structure 205 and 306, which are connected to their respective substrates 203 and 304, and directly coupled to each other.

Each of the subassemblies can be formed separately, encapsulated separately, and then joined together via the interconnect structures and adhesive to form a semiconductor device assembly having face-to-face sub-assemblies.

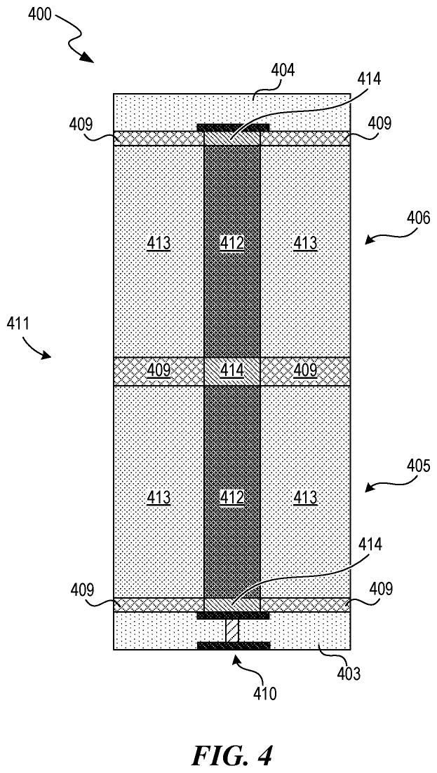

The manner in which these interconnect structures 205 and 306 are coupled is illustrated in greater detail in FIG. 4. Both the first interconnect structure 405 and the second interconnect structure 406 can contain a conductive pillar 412 which can be surrounded by a sheath of dielectric material 413, which is distinct from the encapsulant or molding material that is used to surround the die stacks and the assembly, seen in previous Figures. These conductive pillars 412 can be made of metal or a metal alloy (e.g., Cu, Ni, Ti, Au, W, or alloys thereof), and they can serve different purposes in the overall assembly (e.g., communicating signals, power, or ground, etc.). The dielectric material 413 can be an oxide, a nitride, a polymer, or any other insulating or dielectric material compatible with the formation of the respective subassemblies. These conductive pillars 412 can be joined by a direct coupling 414 (e.g., a solder ball, etc.) which can be surrounded by an encapsulant material or an adhesive 409 to help secure the joint. So joined, the first interconnect structure 405 and the second interconnect structure 406 can form a composite interconnect structure, 411. Although not illustrated, the composite interconnect structure 411 may include a contact pad (e.g., a nickel or copper pad for carrying a solder ball) or under bump metallization (UBM) at either or both ends.

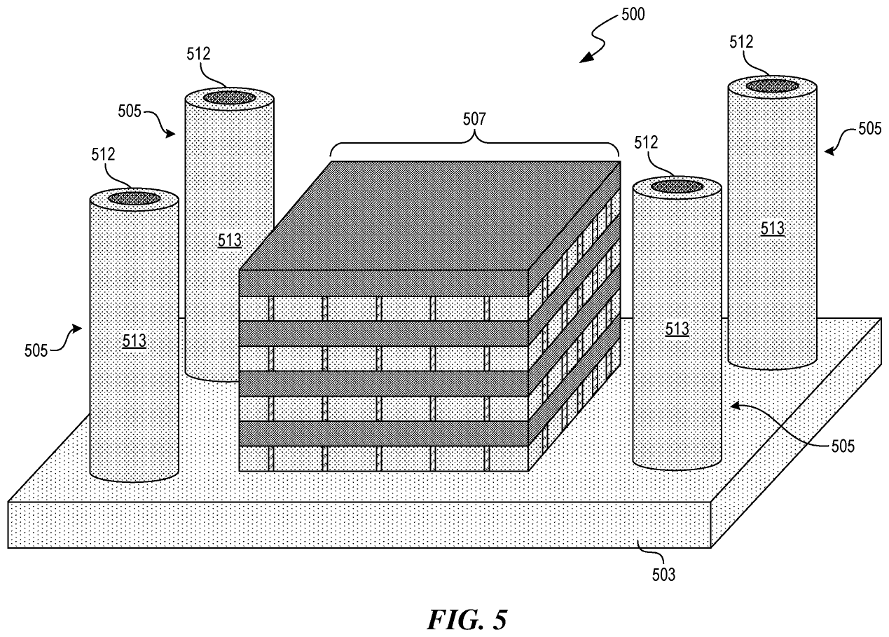

Viewed from an oblique angle, FIG. 5 shows an alternate embodiment of a semiconductor device subassembly 500. This assembly 500 can include multiple interconnect structures 505. The number of these interconnect structures 505 can vary, and they may be placed on all four corners of the semiconductor stack 507, as illustrated, or they may be disposed in any relative position to one another and the stack 507 (e.g., in rows, columns, arrays, etc.). Also, these interconnect structures can possess a discrete region of dielectric material 513 surrounding a conductive pillar 512.

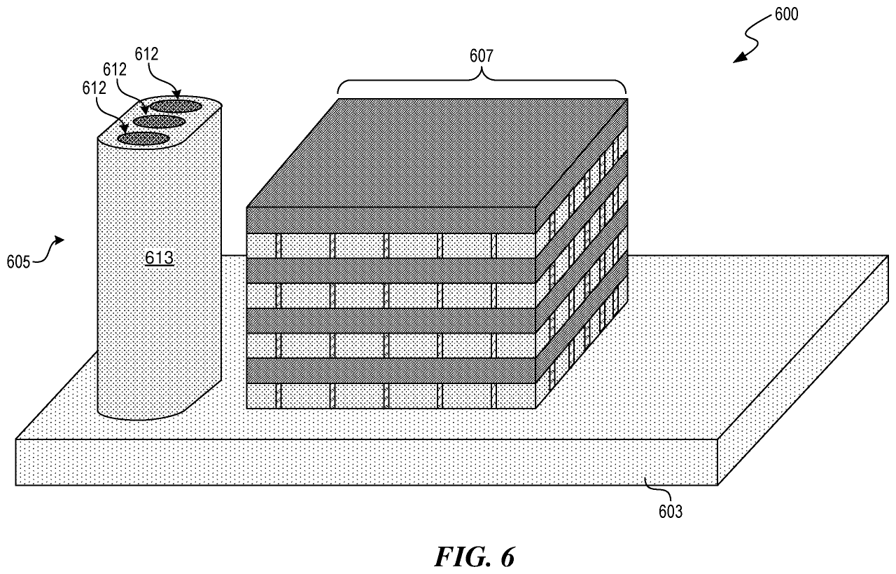

In contrast, FIG. 6 shows a potential embodiment of multiple interconnect structures 605 that can share a single monolithic sheath of dielectric material 613, surrounding and separating a group of conductive pillars 612. This grouped interconnect structure 605 may be disposed anywhere on the substrate 603 relative to the semiconductor stack 607 in the semiconductor device subassembly 600. The number of conductive pillars held within a shared dielectric sheath 613 can vary; additionally, these conductive pillars 612 can be positioned in a line—as illustrated—or in a grid, an array, or any other pattern.

In other embodiments assemblies can have interconnect structures that comprise a mix of groupings. This mix can include a semiconductor device assembly that has both conductive pillars sharing a region of dielectric material along with conductive pillars possessing their own discrete regions of dielectric material, varying according to number and relative position. Additionally, although only illustrated for the first semiconductor subassembly, these same embodiments can be applied to the second semiconductor subassembly, allowing for both subassemblies to be coupled according to the embodiments of their respective interconnect structures.

Although in the foregoing example embodiment semiconductor device assemblies have been illustrated and described as including a specific number of semiconductor devices, in other embodiments assemblies can be provided with more or fewer semiconductor devices. For example, the stack of semiconductor devices illustrated in FIGS. 1, 2, 3, 5, and/or 6 could be replaced with, e.g., a shorter or taller vertical stack of semiconductor devices, a plurality of semiconductor devices, mutatis mutandis.

In accordance with one aspect of the present disclosure, the semiconductor devices illustrated in the assemblies of FIGS. 1-6 could be memory dies, such as dynamic random access memory (DRAM) dies, NOT-AND (NAND) memory dies, NOT-OR (NOR) memory dies, magnetic random access memory (MRAM) dies, phase change memory (PCM) dies, ferroelectric random access memory (FeRAM) dies, static random access memory (SRAM) dies, or the like. In an embodiment in which multiple dies are provided in a single assembly, the semiconductor devices could be memory dies of a same kind (e.g., both NAND, both DRAM, etc.) or memory dies of different kinds (e.g., one DRAM and one NAND, etc.). In accordance with another aspect of the present disclosure, the semiconductor dies of the assemblies illustrated and described above could be logic dies (e.g., controller dies, processor dies, etc.), or a mix of logic and memory dies (e.g., a memory controller die and a memory die controlled thereby).

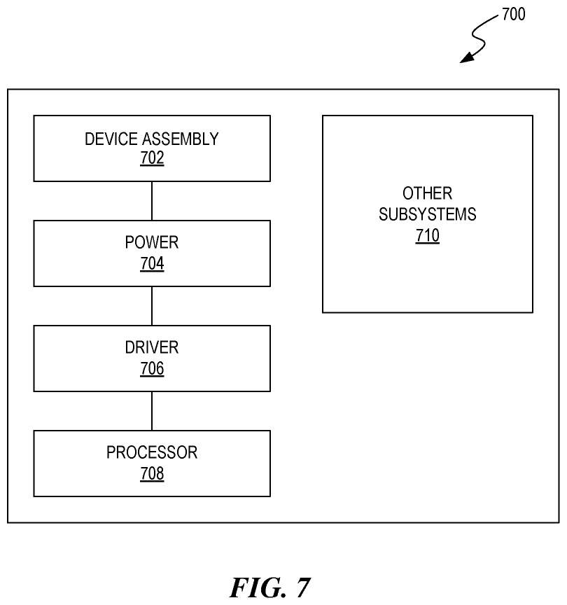

Any one of the semiconductor device subassemblies and semiconductor device assemblies described above with reference to FIGS. 1-6 can be incorporated into any of a myriad of larger and/or more complex systems, a representative example of which is system 700 shown schematically in FIG. 7. The system 700 can include a semiconductor device assembly (e.g., or a discrete semiconductor device) 702, a power source 704, a driver 706, a processor 708, and/or other subsystems or components 710. The semiconductor device assembly 702 can include features generally similar to those of the semiconductor devices described above with reference to FIGS. 1-6. The resulting system 700 can perform any of a wide variety of functions, such as memory storage, data processing, and/or other suitable functions. Accordingly, representative systems 700 can include, without limitation, hand-held devices (e.g., mobile phones, tablets, digital readers, and digital audio players), computers, vehicles, appliances and other products. Components of the system 700 may be housed in a single unit or distributed over multiple, interconnected units (e.g., through a communications network). The components of the system 700 can also include remote devices and any of a wide variety of computer readable media.

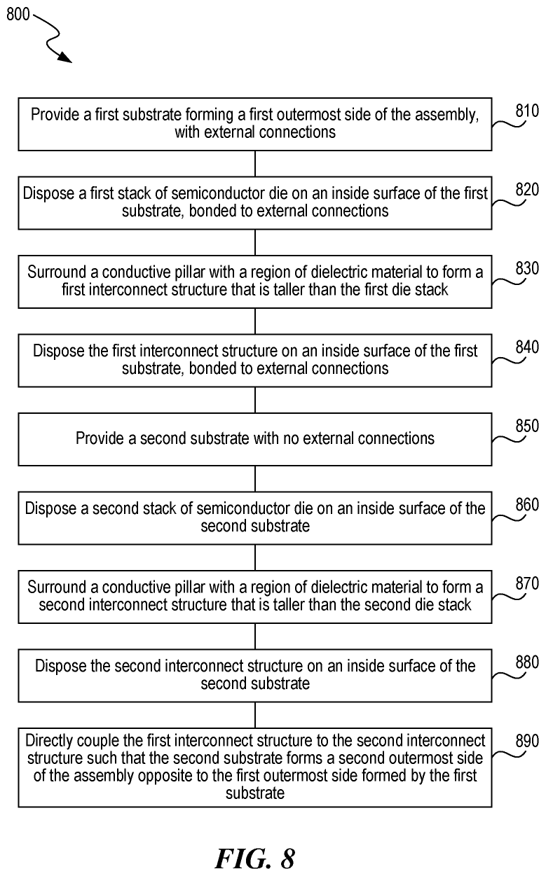

FIG. 8 is a flow chart illustrating a method of making a stacked semiconductor device assembly in a mirrored architecture. The method includes providing a first substrate forming a first outermost side of the assembly, with external connections (box 810). The method further includes disposing a first stack of semiconductor dies on an inside surface of the first substrate, bonded to external connections (box 820). The method further includes surrounding a conductive pillar with a region of dielectric material to form a first interconnect structure that is taller than the first die stack (box 830). The method further includes disposing the first interconnect structure on an inside surface of the first substrate, bonded to external connections (box 840). The method further includes providing a second substrate with no external connections (box 850). The method further includes disposing a second stack of semiconductor dies on an inside surface of the second substrate (box 860). The method further includes surrounding a conductive pillar with a region of dielectric material to form a second interconnect structure that is taller than the second die stack (box 870). The method further includes disposing the second interconnect structure on an inside surface of the second substrate (box 880). The method further includes directly coupling the first interconnect structure to the second interconnect structure such that the second substrate forms a second outermost side of the assembly opposite to the first outermost side formed by the first substrate (box 890).

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a first semiconductor device subassembly, including:
a first substrate having a first inner surface forming a first outermost side of the assembly and a first outer surface,
a first stack of semiconductor dies disposed on the first inner surface, and a first interconnect structure disposed on the first inner surface, having a first conductive pillar, and a first region of dielectric material surrounding the first conductive pillar,
wherein a height of the first stack is less than or equal to a height of the first interconnect structure;
a second semiconductor device subassembly, including:
a second substrate having a second inner surface forming a second outermost side of the assembly and a second outer surface,
a second stack of semiconductor dies disposed on the second inner surface, and
a second interconnect structure disposed on the second inner surface, having a second conductive pillar, and a second region of dielectric material surrounding the second conductive pillar,
wherein the second outermost side is opposite to the first outermost side, and wherein a height of the second stack is less than or equal to a height of the second interconnect structure; and
an encapsulant material at least partially encapsulating the first and second stacks and the first and second interconnect structures,
wherein the encapsulant comprises a different material than the dielectric material, and wherein the first interconnect structure is directly coupled to the second interconnect structure.

2. The semiconductor device assembly of claim 1, wherein there exists a gap between the first and second die stack which is at least partially filled with an adhesive or underfill material.

3. The semiconductor device assembly of claim 1, wherein the first substrate has external connections at the first outermost side of the assembly.

4. The semiconductor device assembly of claim 3, wherein a portion of the external connections are connected to the second die stack through the coupled first and second interconnect structures.

5. The semiconductor device assembly of claim 1, wherein at least one of the first and second die stacks is directly bonded to the corresponding first or second substrate by solder balls or by wire bonds.

6. The semiconductor device assembly of claim 1, wherein at least one of the first and second substrates comprises a printed circuit board or an interface die.

7. The semiconductor device assembly of claim 1, wherein the first and second interconnects are directly coupled via a solder joint.

8. The semiconductor device assembly of claim 7, wherein the solder joint is surrounded by an encapsulant material or adhesive.

9. The semiconductor device assembly of claim 1, wherein:
the first interconnect structure further comprises:
a first group of conductive pillars including the first conductive pillar, wherein the first region of dielectric material surrounds and electrically isolates the first group of conductive pillars,
the second interconnect structure further comprises:
a second group of conductive pillars including the second conductive pillar, wherein the second region of dielectric material surrounds and electrically isolates the second group of conductive pillars.

10. The semiconductor device assembly of claim 1, wherein:
the first semiconductor subassembly further comprises a first group of interconnect structures including the first interconnect structure;
the second semiconductor subassembly further comprises a second group of interconnect structures including the second interconnect structure;
wherein each interconnect structure of the first and second groups includes a single conductive pillar surrounded by a discrete region of dielectric material.

11. The semiconductor device assembly of claim 1, wherein the first conductive pillar is soldered to the first substrate, and the second conductive pillar is soldered to the second substrate.

12. A semiconductor device subassembly, comprising:
a substrate including:
an inner surface, and an outer surface exclusive of any conductive structures;
a stack of semiconductor dies disposed on the inner surface; and
an interconnect structure, including:
a lower surface disposed on the inner surface of the substrate, an upper surface opposite the lower surface, and at least one conductive pillar extending from the lower surface to the upper surface surrounded by a region of dielectric material,
wherein a height of the die stack is less than or equal to a height of the interconnect structure.

13. The semiconductor device subassembly of claim 12, wherein the interconnect structure further comprises a group of conductive pillars including the at least one conductive pillar, and the region of dielectric material surrounds and electrically isolates the group of conductive pillars.

14. The semiconductor device subassembly of claim 12, wherein the interconnect structure is a first interconnect structure, and wherein the subassembly further comprises a second interconnect structure having a second conductive pillar and a second discrete region of dielectric material surrounding the second conductive pillar.

15. The semiconductor device subassembly of claim 12, wherein the interconnect structure further includes a contact pad which is in direct contact with the inner surface of the substrate and with the conductive pillar.

16. The semiconductor device subassembly of claim 15, wherein the interconnect structure is coupled to the substrate by a solder joint.

17. A method of making a semiconductor device assembly, the method comprising:
disposing a stack of semiconductor dies on an inside surface of a substrate having an outer surface opposite the inside surface and exclusive of any conductive structures; and
disposing a lower surface of an interconnect structure on the inside surface of the substrate, the interconnect structure also including an upper surface opposite the lower surface, and at least one conductive pillar extending from the lower surface to the upper surface surrounded by a region of dielectric material,
wherein a height of the die stack is less than or equal to a height of the interconnect
structure.

18. The method of claim 17, wherein a second semiconductor device subassembly comprises the substrate, the die stack, and the interconnect structure, wherein the substrate is a second substrate, the die stack is a second die stack, the interconnect structure is a second interconnect structure, the at least one conductive pillar is a second at least one conductive pillar, and the region of dielectric material is a second region of dielectric material; and wherein the method further comprises:
providing a first semiconductor device subassembly, including:
a first substrate forming a first outermost side of the assembly, a first stack of semiconductor dies disposed on an inside surface of the first substrate, and
a first interconnect structure disposed on the inside surface of the first substrate, having a first at least one conductive pillar surrounded by a first region of dielectric material,
wherein a height of the first stack is less than or equal to a height of the first interconnect structure;
directly coupling the first interconnect structure to the second interconnect structure; and
at least partially encapsulating the first stack, the second stack, the first interconnect structure, and the second interconnect structure with an encapsulant material, wherein the encapsulant comprises a different material than the first and second regions of dielectric material, and
wherein the second substrate forms a second outermost side of the assembly opposite to the first outermost side.

19. The method of claim 18, wherein the first and second interconnect structure are formed separately from the first and second subassembly, before being directly coupled to the first and second substrate, respectively.

20. The method of claim 18, wherein:
the encapsulating occurs before directly coupling the first interconnect to the second interconnect;
the encapsulating comprises:
a first encapsulating of the first stack and the first interconnect structure;
a second encapsulating of the second stack and the second interconnect structure; and
the method further comprises:
applying a layer of adhesive between the first and second subassemblies.
